(19) United States
(12) Patent Application Publication
(10) Pub. No.: US 2026/0239820 A1
(43) Pub. Date: Aug. 13, 2026

(54) LIGHT-EMITTING ELEMENT AND DISPLAY DEVICE

(71) Applicant: Sharp Display Technology Corporation, Kameyama City, Mie (JP)

(72) Inventors: TAZUKO KITAZAWA, Sakai City, Osaka (JP); YOSHIHIRO UETA, Sakai City, Osaka (JP)

(21) Appl. No.: 19/155,739

(22) PCT Filed: Feb. 20, 2023
(86) PCT No.: PCT/JP2023/005935

§ 371 Date: Aug. 12, 2025

(51) Int. Cl. H10K 50/826; H10K 102/20

(52) U.S. Cl. CPC H10K 50/826; H10K 2102/20

(57) ABSTRACT

light-emitting element includes: a first electrode; a second electrode made of a metal-containing layer having a gap penetrating the metal-containing layer; a light-emitting layer positioned between the first electrode and the second electrode; and a particle layer containing a particle and formed in contact with the second electrode. Such features make it possible to achieve high efficiency in injection of electrons in the light-emitting layer and extraction of light at the same time, and, simultaneously, to deposit a film on an electrode layer without a break in the film.

### TECHNICAL FIELD

The present disclosure relates to a light-emitting element and a display device.

### BACKGROUND ART

For light-emitting elements, a metal electrode with a small work function is preferably used as an electrode in order to improve efficiency in injecting electrons into a light-emitting layer. However, the metal electrode has poor light transmittance; that is, poor light extraction efficiency. Hence, for example, Patent Document 1 discloses a display device in which a plurality of opening portions is provided to penetrate a metal electrode layer. Thus, the metal electrode layer achieves high light transparency and high conductivity at the same time.

### CITATION LIST

### Patent Literature

[Patent Document 1] Japanese Unexamined Patent Application Publication No. 2009-230960

### SUMMARY

### Technical Problems

However, as to the display device of Patent Document 1, the opening portions formed in the metal electrode layer have an inner diameter of 10 nm to 780 nm. Hence, if the plurality of opening portions is formed in the metal electrode layer, the metal electrode layer has a surface (an upper surface and a lower surface) with large asperities. When a film is deposited on the surface of the metal electrode layer, the large asperities on the surface of the metal electrode layer are highly likely to cause a break in the film. When the film on the metal electrode layer is broken, the film cannot sufficiently make use of its functions. As a result, the light-emitting element exhibits poor light emission efficiency. As described above, the known technique is not sufficient to achieve higher efficiency in injection of electrons into the light-emitting layer and extraction of light at the same time, or, to deposit a film on an electrode layer without a break in the film.

The present disclosure sets out to provide a light-emitting element successfully achieving high efficiency in injection of electrons into a light-emitting layer and extraction of light at the same time, and, simultaneously, having a film deposited on an electrode layer without a break in the film.

### Solution to Problems

A light-emitting element according to an aspect of the present disclosure includes: a first electrode; a second electrode made of a metal-containing layer having a gap penetrating the metal-containing layer; a light-emitting layer positioned between the first electrode and the second electrode; and a particle layer containing a particle and formed in contact with the second electrode.

### Advantageous Effect of Disclosure

The present disclosure makes it possible to achieve high efficiency in injection of electrons in the light-emitting layer and extraction of light at the same time, and, simultaneously, to deposit a film on an electrode layer without a break in the film.

### BRIEF DESCRIPTION OF DRAWINGS

FIG. 1 is a cross-sectional view illustrating an exemplary configuration of a display device including a light-emitting element according to a first embodiment of the present disclosure.

FIG. 2 is a cross-sectional view illustrating an exemplary configuration of a second electrode of the light-emitting element illustrated in FIG. 1.

FIG. 3 is an illustration citing the Thornton zone model showing structural changes in a sputtered thin film.

FIG. 4 is a photomicrograph of a cross-section of an example of the light-emitting element illustrated in FIG. 1.

FIG. 5 is an image of a result of a simulation of how an electric field distributes with a gap clearance of 3 nm.

FIG. 6 is a graph showing a particle size above the gap and a result of increase in electric field.

FIG. 7 is a graph showing a result of simulation as to a gap clearance and electric field intensity.

FIG. 8 is a cross-sectional view illustrating an exemplary configuration of a display device including a light-emitting element according to a second embodiment of the present disclosure.

FIG. 9 is a cross-sectional view illustrating an exemplary configuration of a display device including a light-emitting element according to a third embodiment of the present disclosure.

FIG. 10 is a cross-sectional view illustrating an exemplary configuration of a display device including a light-emitting element according to a fourth embodiment of the present disclosure.

FIG. 11 is a cross-sectional view illustrating an exemplary configuration of a display device including a light-emitting element according to a fifth embodiment of the present disclosure.

FIG. 12 is data showing a relationship between a gap shape and strength of an electric field directly above the gap.

FIG. 13 is data showing a relationship between a gap shape and strength of an electric field directly above the gap.

FIG. 14 is a schematic view illustrating an exemplary configuration of a display device according to an embodiment.

FIG. 15 is a cross-sectional view illustrating an exemplary configuration of the display device according to an embodiment.

### DESCRIPTION OF EMBODIMENTS

### First Embodiment

### Outline of Light-Emitting Element

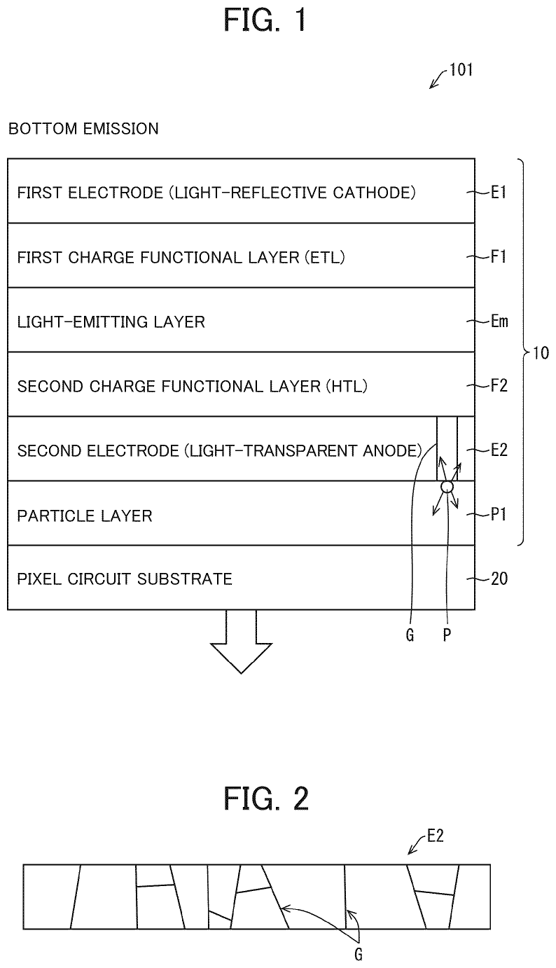

FIG. 1 is a cross-sectional view illustrating an exemplary configuration of a display device 101 including a light-emitting element 10 according to an embodiment of the present disclosure. As illustrated in FIG. 1, the display device 101 includes: a light-emitting element 10; and a pixel circuit substrate 20 for driving the light-emitting element 10. The light-emitting element 10 is provided on the pixel circuit substrate 20. The light-emitting element 10 includes: a first electrode E1; a second electrode E2 facing the first electrode E1; and a light-emitting layer Em positioned between the first electrode E1 and the second electrode E2. The light-emitting element 10 includes: a first charge functional layer (ETL) F1 positioned between the first electrode E1 and the light-emitting layer Em; a second charge functional layer (HTL) F2 positioned between the second electrode E2 and the light-emitting layer Em; and a particle layer P1 positioned between the second electrode E2 and the pixel circuit substrate 20.

Particles P contained in the particle layer P1 may have any given shape. The shape shall not be limited to a three-dimensional spherical shape (a circular cross-section). For example, the shape may have a polygonal cross-section, a bar-like three-dimensional shape, a branch-like three-dimensional shape, or a three-dimensional shape having asperities on the surface. Alternatively, the nanoparticle may have a combination of those shapes. As to a particle size, for example, a cross-section of each of the particles P is observed for 50 particles P closely positioned one another. A diameter is calculated for a circle having an area equivalent to the area of the cross-section of the particle P. An average of the diameters of the 50 particles P may be determined to be the particle size of the particles P.

The first electrode E1 is a light-reflective electrode (a light-reflective cathode), and the second electrode E2 is a light-transparent electrode (a light-transparent anode). As illustrated in FIG. 1, if the pixel circuit substrate 20 is a lowermost layer, and the particle layer P1, the second electrode E2, the second charge functional layer F2, the light-emitting layer Em, the first charge functional layer F1, and the first electrode E1 are sequentially stacked on top of another above the pixel circuit substrate 20, the first electrode E1 is a light-reflective electrode positioned above the second electrode E2, and the particle layer P1 is in contact with a lower surface of the second electrode E2. Here, the term above means that the first electrode E1 is a layer positioned farther way from the pixel circuit substrate 20 than a comparative layer. Furthermore, the second electrode E2 is made of a metal-containing layer having a gap G penetrating the metal-containing layer. The light-emitting layer Em contains a plurality of quantum dots. Each of the first charge functional layer F1 and the second charge functional layer F2 may include one or more functional layers such as a charge injection layer, a charge transport layer, and a charge-blocking layer. The particle layer P1 exhibits electrical conductivity, has contact with the lower surface of the second electrode E2, and contains metal oxide particles such as, for example, the plurality of particles P made of titanium oxide. The pixel circuit substrate 20 is an active substrate provided with circuit elements and wires. Note that the gap G of the metal-containing layer included in the second electrode E2 will be described in detail later.

FIG. 1 shows that the light-emitting element 10 includes: the particle layer P1; the second electrode E2; the second charge functional layer F2; the light-emitting layer Em; the first charge functional layer F1; and the first electrode E1, all of which are sequentially stacked on top of another above the pixel circuit substrate 20. As to this configuration, the light-emitting element 10 is a bottom-emission light-emitting element, the first electrode E1 is a cathode, and the second electrode E2 is an anode. Such a configuration shall not limit the scope of the present disclosure. For example, the light-emitting element 10 may be a top-emission light-emitting element.

The first charge functional layer F1 includes a hole transport layer HTL. The hole transport layer HTL may be formed of a hole-transporting material capable of stably transporting holes into the light-emitting layer Em. Examples of the hole-transporting material include poly[(9,9-dioctylfluorenyl-2,7-diyl)-co-(4,4′-(N-4-sec-butylphenyl))diphenylamine)] (TFB) and poly[N, N′-bis(4-butylphenyl)-N, N′-bis(phenyl)benzidine] (poly-TPD). These hole-transporting materials may be used alone or in combination of two or more.

The second charge functional layer F2 includes an electron transport layer ETL. The electron transport layer ETL may be formed of an electron-transporting material capable of stably transporting electrons into the light-emitting layer Em. Examples of the electron-transporting material include, in addition to MgZnO, nanoparticles containing one or more elements selected from the group consisting of Zn, Mg, Ti, Si, Sn, W, Ta, Ba, Zr, Al, Y, and Hf. These electron-transporting materials may also be used alone or in combination of two or more.

The light-emitting layer Em is either an organic light-emitting layer or a quantum-dot light-emitting layer. Here, the light-emitting element including an organic light-emitting layer as the light-emitting layer Em is an organic light-emitting diode (an OLED). The light-emitting element including a quantum-dot light-emitting layer as the light-emitting layer Em is a quantum-dot light-emitting diode (a QLED). The quantum dots are dots each having a maximum width of 100 nm or less. A quantum dot may have any given shape as long as the maximum width of the quantum dot is within the above range. The shape of the quantum dot shall not be limited to a spherical shape (a circular cross-section). For example, the quantum dot may have a polygonal cross-section, a bar-like three-dimensional shape, a branch-like three-dimensional shape, or a three-dimensional shape having asperities on the surface. Alternatively, the quantum dot may have a combination of those shapes.

The gap G is a region not containing the material of the second electrode E2 (the metal-containing layer). The gap G is a region penetrating the second electrode E2 (the metal-containing layer) in a thickness direction. This region contains at least one of the air, an argon gas, or a material directly above the second electrode E2. For example, a structure of the gap G can be observed in cross-section with such devices as the SEM and the TEM. Moreover, an element of an adhering gas can be identified by elemental analyses such as the EDX and gas chromatography.

### Forming Gap G.

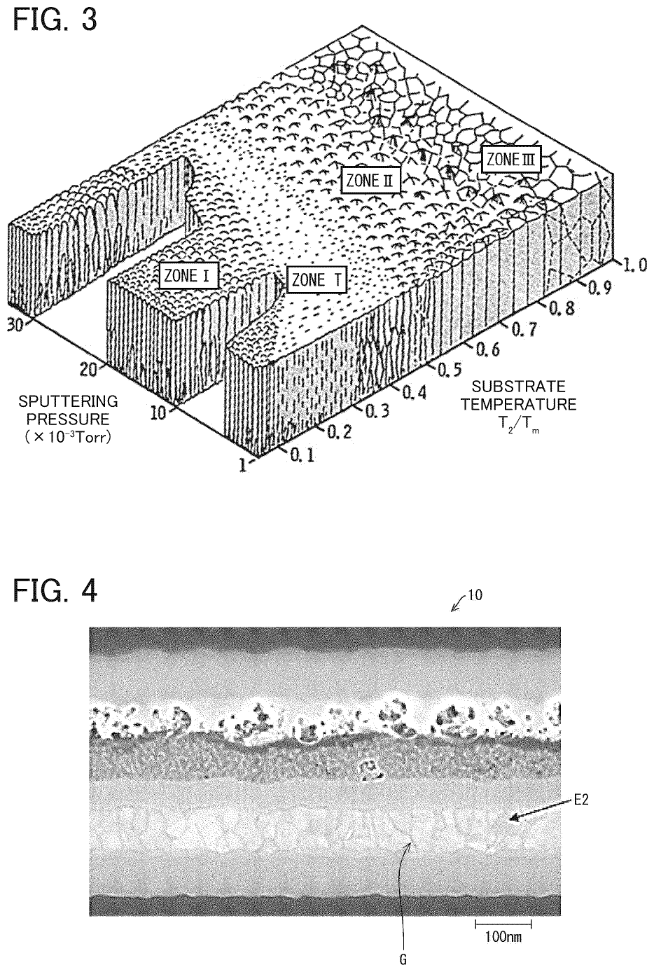

FIG. 2 is a cross-sectional view illustrating an exemplary configuration of the second electrode E2 of the light-emitting element 10 illustrated in FIG. 1. FIG. 3 is an illustration citing the Thornton zone model showing structural changes in a sputtered thin film. FIG. 4 is a photomicrograph of a cross-section of an example of the light-emitting element 10 illustrated in FIG. 1.

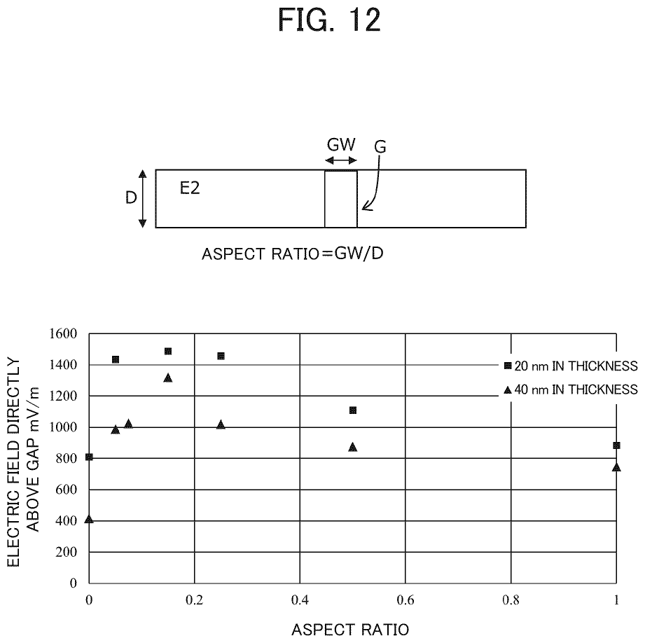

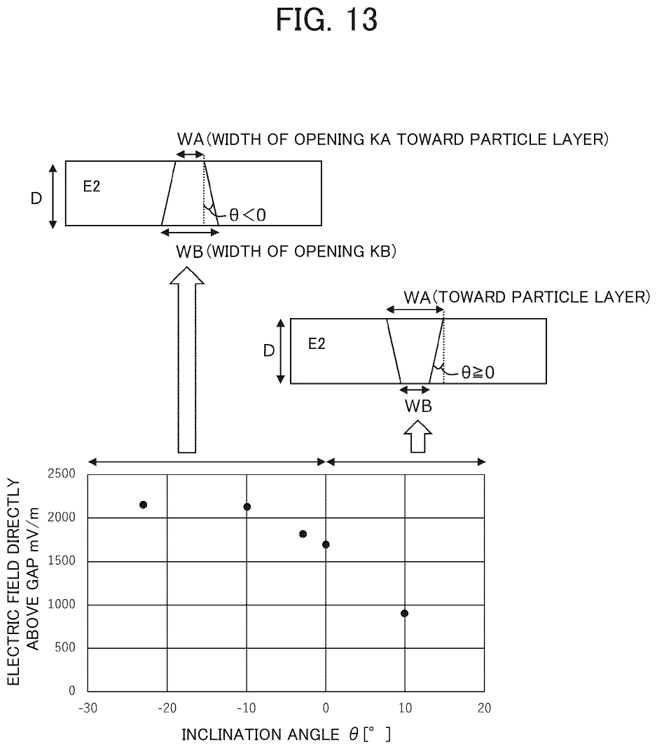

As illustrated in FIG. 2, the gap G penetrates the metal-containing layer included in the second electrode E2. The gap G may be formed into any given shape as long as the gap G penetrates the second electrode E2. As illustrated in FIG. 2, the gap G may be either linear or curved. The gap G may be either parallel or angled to the thickness direction. FIGS. 12 and 13 are data showing a relationship between a gap shape and strength of an electric field directly above the gap. FIG. 12 shows that, for the gap G formed in the second electrode E2, a ratio (an aspect ratio) of a gap width GW to a thickness D of the second electrode E2 is preferably 1.0 or less. The gap width GW may be an average width of the gap G across the total length. As illustrated in FIG. 13, the gap G has: an opening KA positioned on one of faces of the second electrode E2 and facing the particle layer P1; and an opening KB positioned on another one of the faces of the second electrode E2 and not facing the particle layer P1. A width WA of the opening KA is preferably smaller than a width WB of the opening KB. FIG. 13 shows that where D represents the thickness of the second electrode E2 (the metal-containing layer), a relationship of tanθ=(WA−WB)/2D holds, and that where a relationship of an inclination angle θ<0 holds, an electric field directly above the gap is enhanced.

As can be seen, the gap G penetrating the second electrode E2 can be introduced by adjusting sputtering conditions (temperature and pressure) set when the second electrode E2 is deposited not by typical vapor deposition but by sputtering. For example, when the second electrode E2 is deposited by sputtering, a glass substrate is heated to a temperature of as high as approximately 200° C., and an argon gas is introduced to apply a pressure of approximately 1 Pa. Then, a material of the second electrode E2 is deposited. Here, the material of the second electrode E2 is preferably aluminum (Al) or silver (Ag). Hence, the second electrode E2 contains either aluminum or silver. The sputtering conditions and a state of the film are known as the Thornton zone model in FIG. 3. According to this zone model, a clearance of the gap G can be controlled. When a partial pressure of argon is fixed and the temperature of the substrate is lowered, a film is formed continuously in the thickness direction of the layer to have a substantially columnar shape. That is, the gap G can be introduced into the second electrode E2. If the gap G is introduced into the second electrode E2, a preferable sputtering condition is a ZONE II sputtering condition of the Thornton zone model illustrated in FIG. 3. When formed under the condition of ZONE II, the gap G is shaped in the thickness direction of the layer. However, the zone shall not be limited to ZONE II. Alternatively, ZONE III is also applicable.

As to the light-emitting element 10, the second electrode E2 is deposited. After that, the second charge functional layer (HTL) F2, the light-emitting layer Em, and the first charge functional layer (ETL) F1 are formed into a multilayer structure by typical coating or ink-jet printing. Finally, the first electrode E1 (the cathode) is vacuum-deposited so that the element structure is sealed. FIG. 4 is a cross-sectional SEM image of the light-emitting element 10 produced in this manner. As illustrated in FIG. 4, the gap G can be observed in the second electrode E2.

### Light Extraction Efficiency and Gap G

As described above, the gap G is found in the second electrode E2. When the light from the light-emitting layer Em enters the second electrode E2, gap plasmons are excited in the gap G. The gap plasmons are light localized in the gap G. Since the particles P of the particle layer P1 are found in a range in which this light is distributed (a range in which the light leaks), the gap plasmons are transformed into propagating light. That is, the particles P are found preferably above the gap G.

The statement “above the gap” may include a case where the particles P are at least partially found in a range of the clearance of the gap G, and a case where, as to the gap G formed on the surface of the second electrode E2, the particles P are at least partially found in a range of the particle layer P1 in relation to the clearance of the gap G. That is, the plurality of particles P contained in the particle layer P1 scatter the light amplified by the plasmons generated in the gap G.

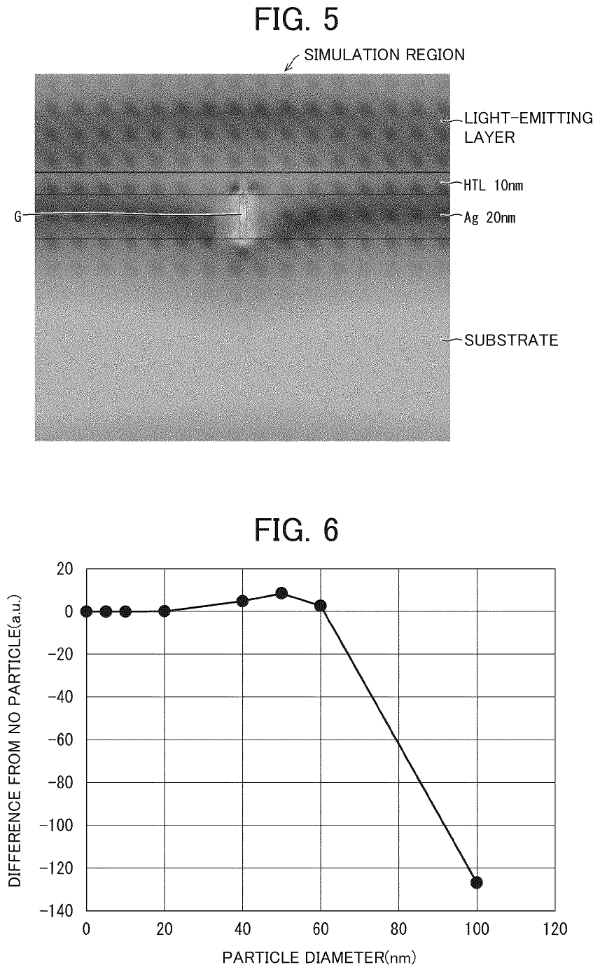

FIG. 5 shows a result of a simulation of how an electric filed distributes near the gap G formed in the second electrode E2; that is, a layer of Ag having a thickness of 20 nm. Introduced into the second electrode E2 is a plurality of the gaps G. For the sake of brevity, this simulation is carried out with one gap G. This simulation is carried out without the particles P; that is, without the particle layer P1 on the substrate. Instead, the Ag layer, which serves as the second electrode E2, is directly formed on the substrate. Here, the gap G has a clearance of 3 nm. The clearance of the gap G is defined as an average width of the opening formed with the gap G in an opening face on the surface of the second electrode E2. For example, if the gap G is cylindrical, the clearance of the gaps G is equal to a diameter of the cylinder. That is, the cylindrical gap G forms a circular through hole (a circular opening) on the surface of the second electrode E2. In this case, the clearance of the gap G can be described as the diameter of the gap G. Furthermore, if the through hole is elliptical, an average axis of the major axis and the minor axis can be described as the clearance of the gap G.

Found above the second electrode E2 is the second charge functional layer (HTL) having a thickness of 10 nm and a refractive index of 1.4. Found above the second charge functional layer (HTL) is a light-emitting face of a plane wave having a wavelength of 400 nm excited by an electric field of 1 V/m. Below the second electrode E2, the particle layer P1 is omitted, and a layer having a refractive index of 1.5 is set as the pixel circuit substrate 20 and provided to an end of the simulation region. As seen in FIG. 5, a strong electric field (the gap plasmons) is excited in the gap G having a significantly narrow clearance of 3 nm with respect to the light having a wavelength of 400 nm and sent from toward the light-emitting face. FIG. 5 shows that the light leaks to an upper plane of the gap G (toward the pixel circuit substrate 20).

FIG. 6 is a result of a simulation of how an electric filed is amplified at an end of the simulation region when the particles P formed of TiO₂ and contained in the particle layer P1 are found above the gap G. Here, the statement that the TiO₂ particles have a particle size of 0 nm means that no TiO₂ particles is found. The result of the simulation shows that, when the TiO₂ particles are found, if the TiO 2 particles have a particle size of 60 nm or less, the leaking light of the gap plasmons is scattered so that the intensity is amplified. Whereas, if the TiO₂ particles have a particle size of more than 60 nm, the gap plasmons are less likely to be excited such that no advantageous effect is observed. Hence, the particles P of the particle layer P1 have an average particle size of preferably 60 nm or less. Furthermore, the average particle size of the particles P is set to preferably 1/10 of a peak emission wavelength with which the light scatters at strong intensity.

As described above, the gap plasmons are excited in the gap G introduced into the second electrode E2. Then, the excited gap plasmons are scattered with the plurality of particles P of the particle layer P1. As a result, such a feature can increase a transmittance (light extraction efficiency) of the light sent from the light-emitting layer Em and transmitted through the second electrode E2.

### Relationship Between Clearance of Gap G and Light Extraction Efficiency

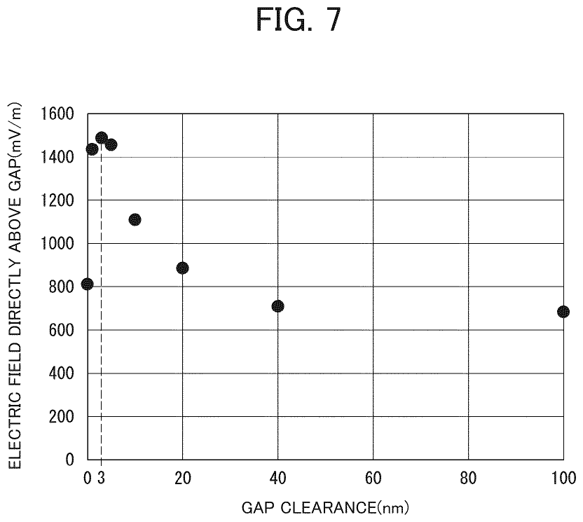

The graph in FIG. 7 shows a simulation of the gap G with the clearance (hereinafter referred to as a gap clearance) varied. Plotted on the graph is a relationship between intensity of the electric field excited directly above the gap G and a gap clearance. This graph shows that a strong electric field is generated since the gap clearance marks a peak of 3 nm. Here, a gap clearance of 0 nm represents a case where no gap G is found, and the range in which the electric field here is 800 m V/m or more is a range in which the gap G exhibits an advantageous effect. Hence, in order to enhance the light extraction efficiency, the gap clearance is preferably deemed to be 20 nm or less. Here, the particles P of the particle layer P1 have an average particle size of preferably 60 nm or less.

### Advantageous Effects

As can be seen, the sputtering condition is adjusted so that the second electrode E2 formed of metal simultaneously achieves high electrical conductivity, (a small work function), high light extraction efficiency and high reliability (i.e., no leakage or break due to asperities), and the particle layer P1 is formed by a regular application technique. The resulting light-emitting element 10 can simultaneously satisfy the features below.
(1) An electrode with a small work function can be formed, and the electrode is suitable to inject electrons into the second charge functional layer (HTL). That is, the electrode can increase efficiency in injecting the electrons into the light-emitting layer Em.
(2) The gap plasmons excited in the gap G are transformed into propagating light, thereby successfully increasing efficiency in extracting light from the second electrode E2.
(3) The surface of the second electrode E2 including the gap G has only small asperities. Such a feature reduces the risk of breaking a layer to be formed on the surface, thereby reducing the risks of leakage and a break.

Note that this embodiment exemplifies a case where the second electrode E2 is an anode and the second electrode E2 and the particle layer P1 function as features. Alternatively, even if the second electrode E2 serves as a cathode, the same advantageous effects are achieved as long as the gap G is provided similarly to the second electrode E2 and the particles P are included in the particle layer P1.

### Second Embodiment

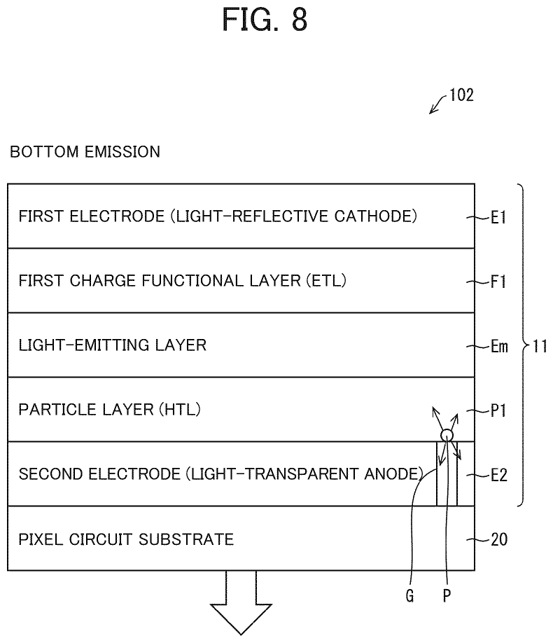

FIG. 8 is a cross-sectional view illustrating an exemplary configuration of a display device 102 including a light-emitting element 11 according to another embodiment of the present disclosure. As illustrated in FIG. 8, the pixel circuit substrate 20 is the same between the display device 102 of this embodiment and the display device 101 of the first embodiment; whereas, a multilayer structure is different between the light-emitting element 11 of the display device 102 and the light-emitting element 10 of the display device 101. Specifically, the light-emitting element 11 includes: the second electrode E2; the particle layer P1; the light-emitting layer Em; the first charge functional layer F1; and the first electrode E1, all of which are sequentially stacked on top of another above the pixel circuit substrate 20. Note that like reference signs designate identical members between the light-emitting element 11 of this embodiment and the light-emitting element 10 of the first embodiment. These members will not be elaborated upon here.

The light-emitting element 11 is the same as the light-emitting element 10 illustrated in FIG. 1 as to a positional relationship between the first electrode E1 and the second electrode E2. Whereas, the light-emitting element 11 is different from the light-emitting element 10 in that not the particle layer P1 but the second electrode E2 is formed directly above the pixel circuit substrate 20, and the particle layer P1 is formed above the second electrode E2. The particle layer P1 is formed in contact with an upper surface of the second electrode E2. Furthermore, in the light-emitting element 11, the particle layer P1 functions as the hole transport layer HTL. That is, the particle layer P1 contains, as the particles P, metal oxide particles having a hole-transporting function. The metal oxide is preferably, for example, nickel oxide. In this case, the particles P contained in the particle layer P1 are nickel oxide particles.

When the particle layer P1 above the second electrode E2 contains the particles P having a particle size smaller than, or equal to, the clearance of the gap G in the second electrode E2, the particles P enter the gap G and reduce the excitation of the gap plasmons. Hence, in this embodiment, an average width (a gap clearance) of an opening, which is formed in an opening face on the surface of the second electrode E2 when the gap G penetrates the second electrode E2, is set to be smaller than, or equal to, an average particle size of the plurality of particles P contained in the particle layer P1 above the second electrode E2. Hence, as the graph in FIG. 7 of the first embodiment shows, the gap clearance is preferably 20 nm or less, and smaller than, or equal to, the average particle size of the particles P contained in the particle layer P1.

### Advantageous Effects

Similar to the display device 101 of the first embodiment, the display device 102 in the above configuration has the second electrode E2 provided with the gap G and the particle layer P1 containing particles P. Hence, the display device 102 achieves the same advantageous effects as the advantageous effects of the display device 101 of the first embodiment. That is, the sputtering conditions are adjusted so that the second electrode E2 formed of metal simultaneously achieves high electrical conductivity, (a small work function), high light extraction efficiency and high reliability (i.e., no leakage or break due to asperities), and the particle layer P1 is formed by a regular application technique. The resulting light-emitting element 11 can simultaneously satisfy the features below.
(1) An electrode with a small work function can be formed, and the electrode is suitable to inject electrons into the particle layer P1 (HTL). That is, the electrode can increase efficiency in injecting the electrons into the light-emitting layer Em.
(2) The gap plasmons excited in the gap G are transformed into propagating light, thereby successfully increasing efficiency in extracting light from the second electrode E2.
(3) The surface of the second electrode E2 including the gap G has only small asperities. Such a feature reduces the risk of breaking a layer to be formed on the surface, thereby reducing the risks of leakage and a break.

Note that this embodiment exemplifies a case where the second electrode E2 is an anode and the second electrode E2 and the particle layer P1 function as features. Alternatively, even if the second electrode E2 serves as a cathode, the same advantageous effects are achieved as long as the gap G is provided similarly to the second electrode E2 and the particles P are included in the particle layer P1.

### Third Embodiment

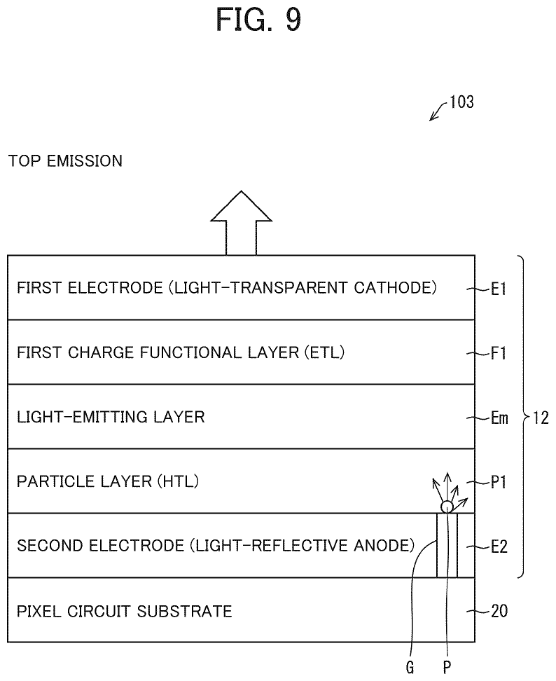

FIG. 9 is a cross-sectional view illustrating an exemplary configuration of a display device 103 including a light-emitting element 12 according to another embodiment of the present disclosure. As illustrated in FIG. 9, the pixel circuit substrate 20 is the same between the display device 103 of this embodiment and the display device 102 of the second embodiment, and the multilayer structure is the same between the light-emitting element 12 of the display device 103 and the light-emitting element 11 of the display device 102; whereas, functions of the first electrode E1 and the second electrode E2 are different between the light-emitting element 12 and the light-emitting element 11. Specifically, the first electrode E1 is positioned above the second electrode E2, and is a light-transparent electrode (a light-transparent cathode). Whereas, the second electrode E2 has a plurality of the gaps G, and is a light-reflective electrode (a light-reflective anode). Hence, as to the display device 103, light is emitted from the first electrode E1 stacked at a farthest position from the pixel circuit substrate 20. That is, the display device 103 is what is referred to as a top-emission display device.

The light-emitting element 12 is the same as the light-emitting element 10 illustrated in FIG. 1 as to a positional relationship between the first electrode E1 and the second electrode E2. Whereas, the light-emitting element 12 is different from the light-emitting element 10 in that not the particle layer P1 but the second electrode E2 is formed directly above the pixel circuit substrate 20, and the particle layer P1 is formed above the second electrode E2. The particle layer P1 is formed in contact with an upper surface of the second electrode E2. Furthermore, in the light-emitting element 12, the particle layer P1 functions as the hole transport layer HTL. That is, the particle layer P1 contains, as the particles P, metal oxide particles having a hole-transporting function. The metal oxide is preferably, for example, nickel oxide. In this case, the particles P contained in the particle layer P1 are nickel oxide particles.

### Advantageous Effects

Similar to display device 102 of the second embodiment, the display device 103 in the above configuration has the second electrode E2 provided with the gaps G and the particle layer P1 containing particles P. Hence, the only difference between the display device 103 of this embodiment and the display device 102 of the second embodiment is that the former is a top-emission display device, and the latter is a bottom-emission display device. The display device 103 achieves the same advantageous effects as those of the display device 102 of the second embodiment. That is, the sputtering conditions are adjusted so that the second electrode E2 formed of metal simultaneously achieves high electrical conductivity, (a small work function), high light extraction efficiency and high reliability (i.e., no leakage or break due to asperities), and the particle layer P1 is formed by a regular application technique. The resulting light-emitting element 12 can simultaneously satisfy the features below.
(1) An electrode with a small work function can be formed, and the electrode is suitable to inject electrons into the particle layer P1 (HTL). That is, the electrode can increase efficiency in injecting the electrons into the light-emitting layer Em.
(2) The gap plasmons excited in the gaps G are transformed into propagating light, thereby successfully increasing efficiency in extracting light from the second electrode E2.
(3) The surface of the second electrode E2 including the gaps G has only small asperities. Such a feature reduces the risk of breaking a layer to be formed on the surface, thereby reducing the risks of leakage and a break.

Note that this embodiment exemplifies a case where the second electrode E2 is an anode and the second electrode E2 and the particle layer P1 function as features. Alternatively, even if the second electrode E2 serves as a cathode, the same advantageous effects are achieved as long as the gaps G are provided similarly to the second electrode E2 and the particles P are included in the particle layer P1.

### Fourth Embodiment

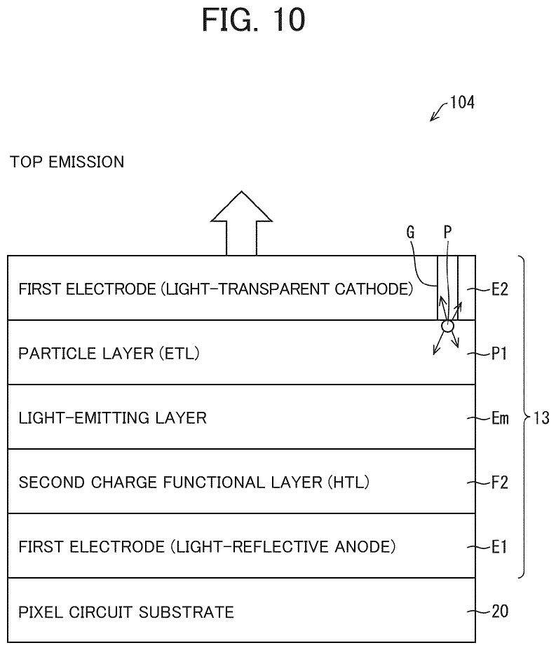

FIG. 10 is a cross-sectional view illustrating an exemplary configuration of a display device 104 including a light-emitting element 13 according to yet another embodiment of the present disclosure. As illustrated in FIG. 10, the pixel circuit substrate 20 is the same between the display device 104 of this embodiment and the display device 103 of the third embodiment; whereas, a multilayer structure is different between the light-emitting element 13 of the display device 104 and the light-emitting element 12 of the display device 103. Specifically, the light-emitting element 13 includes: the first electrode E1; the second charge functional layer F2; the light-emitting layer Em; the particle layer P1; and the second electrode E2, all of which are sequentially stacked on top of another above the pixel circuit substrate 20.

The light-emitting element 13 is different from the light-emitting element 12 in FIG. 9 in that the first electrode E1, the second electrode E2 and the particle layer P1 switch positions with one another. Hence, if the pixel circuit substrate 20 is positioned lowermost, the first electrode E1 is positioned below the second electrode E2 and, moreover, is a light-reflective electrode (a light-reflective anode). Furthermore, the particle layer P1 is formed in contact with a lower surface of the second electrode E2. Whereas, the second electrode E2 has the plurality of gaps G, and is a light-transparent electrode (a light-transparent cathode). Hence, as to the display device 104, light is emitted from the second electrode E2 stacked at a farthest position from the pixel circuit substrate 20. That is, the display device 104 is what is referred to as a top-emission display device. Furthermore, in the light-emitting element 13, the particle layer P1 functions as the electron transport layer ETL. That is, the particle layer P1 contains, as the particles P, metal oxide particles having an electron-transporting function. The metal oxide is, for example, zinc oxide. If the metal oxide is capable of transporting electrons, the metal oxide shall not be limited to zinc oxide. The metal oxide may be titanium oxide.

### Advantageous Effects

Similar to the display device 103 of the third embodiment, the display device 104 in the above configuration has the second electrode E2 provided with the gaps G and the particle layer P1 containing particles P. Hence, the display device 102 achieves the same advantageous effects as the advantageous effects of the display device 103 of the third embodiment. That is, the sputtering condition is adjusted so that the second electrode E2 formed of metal simultaneously achieves high electrical conductivity, (a small work function), high light extraction efficiency and high reliability (i.e., no leakage or break due to asperities), and the particle layer P1 is formed by a regular application technique. The resulting light-emitting element 13 can simultaneously satisfy the features below.
(1) An electrode with a small work function can be formed, and the electrode is suitable to inject electrons into the particle layer P1 (ETL). That is, the electrode can increase efficiency in injecting the electrons into the light-emitting layer Em.
(2) The gap plasmons excited in the gaps G are transformed into propagating light, thereby successfully increasing efficiency in extracting light from the second electrode E2.
(3) The surface of the second electrode E2 including the gaps G has only small asperities. Such a feature reduces the risk of breaking a layer to be formed on the surface, thereby reducing the risks of leakage and a break.

### Fifth Embodiment

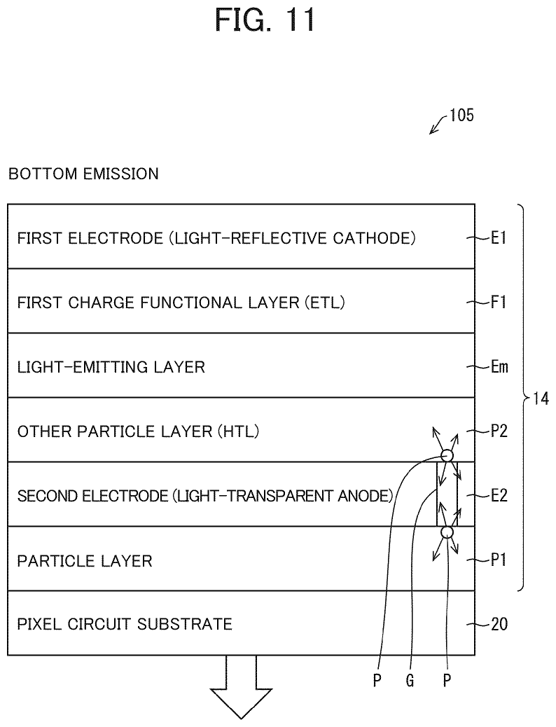

FIG. 11 is a cross-sectional view illustrating an exemplary configuration of a display device 105 including a light-emitting element 14 according to yet another embodiment of the present disclosure. As illustrated in FIG. 11, the display device 105 of this embodiment is different from the display device 101 of the first embodiment in that the display device 105 includes another particle layer P2 instead of the second charge functional layer F2. The other particle layer P2 functions as a hole transport layer (HTL), and, furthermore, contains a plurality of metal oxide particles. The metal oxide particles include, for example, nickel oxide particles. Furthermore, the other particle layer P2 is formed on an upper surface of the second electrode E2.

Hence, the light-emitting element 14 includes: the particle layer P1 in contact with one of the upper surface or the lower surface of the second electrode E2; and the other particle layer P2 in contact with another one of the upper surface or the lower surface of the second electrode E2. Thus, the light-emitting element 14 has layers (the particle layer P1 and the other particle layer P2) containing the particles P and provided on the upper surface and the lower surface of the second electrode E2. Hence, the gap plasmons excited in the gap G of the second electrode E2 can be transformed, using the particles P, into propagating light on both the upper surface and the lower surface of the second electrode E2. Such a feature can significantly increase efficiency in extracting light from the second electrode E2.

### Advantageous Effects

The display device 105 in the above configuration has the same advantageous effects as those of the other embodiments except for the advantageous effects described above. That is, the sputtering conditions are adjusted so that the second electrode E2 formed of metal simultaneously achieves high electrical conductivity, (a small work function), high light extraction efficiency and high reliability (i.e., no leakage or break due to asperities), and the particle layer P1 is formed by a regular application technique. The resulting light-emitting element 14 can simultaneously satisfy the features below.
(1) An electrode with a small work function can be formed, and the electrode is suitable to inject electrons into the other particle layer P2 (HTL). That is, the electrode can increase efficiency in injecting the electrons into the light-emitting layer Em.
(2) The surface of the second electrode E2 including the gap G has only small asperities. Such a feature reduces the risk of breaking a layer to be formed on the surface, thereby reducing the risks of leakage and a break.

The above configurations make it possible to achieve high efficiency in injection of electrons in the light-emitting layer and extraction of light at the same time, and, simultaneously, to deposit a film on an electrode layer without a break in the film. Such advantageous effects also contribute to the achievement of Goal 12 of the Sustainable Development Goals (SDGs) advocated by the United Nations, “Ensuring sustainable production and consumption patterns”, for example.

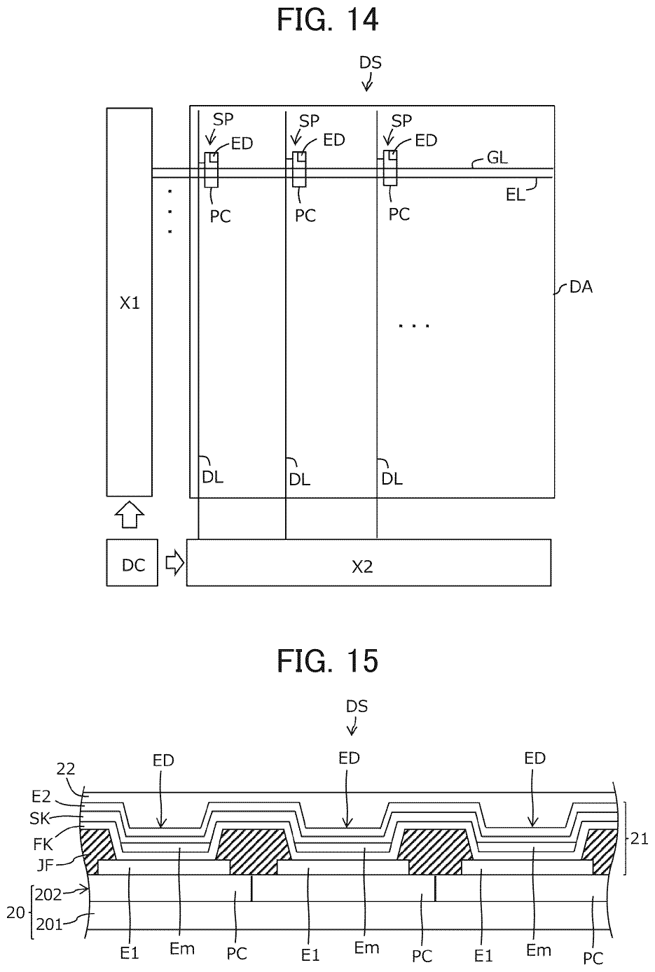

FIG. 14 is a schematic view illustrating an exemplary configuration of a display device according to an embodiment. FIG. 15 is a cross-sectional view illustrating an exemplary configuration of the display device according to the embodiment. As illustrated in FIG. 14, a display device 105 includes: a display unit DA including a plurality of subpixels SP; a first driver X1 and a second driver X2 that drive the plurality of subpixels SP; and a display control unit DC that controls the first driver X1 and the second driver X2. Each of the subpixels SP includes: the light-emitting element 10; and a pixel circuit PC connected to the light-emitting element 10. The pixel circuit PC may be connected to a scan signal line GL, a data signal line, and a light-emission control line DL. The scan signal line GL and the light-emission control line EL may be connected to the first driver X1, and the data signal line DL may be connected to the second driver X2. The light-emitting element 10 is an example, and can be replaced with any one of the light-emitting elements 11, 12, 13, and 14 to form the display devices 101, 102, 103, and 104.

The display device 101 may include: a pixel circuit substrate 20 including a substrate 201 and a pixel circuit layer 202; a light-emitting-element layer 21; and a sealing layer 22. The substrate 201 may be, for example, a glass substrate and a resin substrate. The substrate 201 may be flexible. The pixel circuit layer 202 includes, for example, a plurality of the pixel circuits PC arranged in an inorganic matrix. The pixel circuit PC may include: a pixel capacitor in which a grayscale signal is written; a transistor that controls a current value of the light-emitting element ED in accordance with the grayscale signal; a transistor connected to the scan signal line GL and the data signal line DL; and a transistor connected to the light-emission control line EL.

As illustrated in FIG. 15, a display device DS includes: the pixel circuit substrate 20; and the light-emitting-element layer 21. The light-emitting-element layer 21 may include: the first electrode E1; an edge cover film JF covering an edge of the first electrode E1; a first functional layer FK; the light-emitting layer (a quantum-dot layer) Em; a second functional layer SK; and the second electrode E2, all of which are sequentially provided from toward the pixel circuit substrate 20. The first functional layer FK may have a hole-injection function and a hole-transporting function, and the second functional layer SK may have an electron-transporting function. The light-emitting-element layer 21 may include: a light-emitting element ED including a light-emitting layer Em that emits a red light; a light-emitting element ED including a light-emitting layer Em that emits a green light; and a light-emitting element ED including a light-emitting layer Em that emits a blue light. The sealing layer 22 includes an inorganic insulating film such as a silicon nitride film or a silicon oxide film, and prevents a foreign substance (e.g., water and oxygen) from entering the light-emitting-element layer 21. The light-emitting element ED may be any one of the light-emitting elements 10 to 14 described above, and the display device DS may be any one of the display devices 101 to 105.

Each of the above-described embodiments is presented not for limitative purposes but for illustrative and descriptive purposes. It will be apparent to those skilled in the art that many variations are applicable in accordance with these illustrations and descriptions.

1. A light-emitting element, comprising:
a first electrode;
a second electrode made of a metal-containing layer having a gap penetrating the metal-containing layer;
a light-emitting layer positioned between the first electrode and the second electrode; and
a particle layer containing a particle and formed in contact with the second electrode.

2. The light-emitting element according to claim 1,
wherein an average width of an opening, which is formed in an opening face on a surface of the metal-containing layer when the gap penetrates the metal-containing layer, is 20 nm or less.

3. The light-emitting element according to claim 1,
wherein an average width of an opening, which is formed in an opening face on a surface of the metal-containing layer when the gap penetrates the metal-containing layer, is smaller than, or equal to, a particle size of the particle.

4. The light-emitting element according to claim 1,
wherein the first electrode is a light-reflective electrode positioned above the second electrode, and
the particle layer is in contact with a lower surface of the second electrode.

5. The light-emitting element according to claim 4,
wherein the particle is metal oxide and conductive.

6. The light-emitting element according to claim 5,
wherein the metal oxide is titanium oxide.

7. The light-emitting element according to claim 1,
wherein the first electrode is a light-reflective electrode positioned above the second electrode, and
the particle layer is in contact with an upper surface of the second electrode.

8. The light-emitting element according to claim 7,
wherein the particle is metal oxide and has a hole-transporting function.

9. (canceled)

10. The light-emitting element according to claim 1,
wherein the first electrode is a light-transparent electrode positioned above the second electrode, and
the particle layer is in contact with an upper surface of the second electrode.

11.-14. (canceled)

15. The light-emitting element according to claim 1,
wherein the first electrode is a light-reflective electrode positioned below the second electrode, and
the particle layer is in contact with a lower surface of the second electrode.

16. The light-emitting element according to claim 15,
wherein the particle is metal oxide and has an electron-transporting function.

17. The light-emitting element according to claim 16,
wherein the metal oxide is zinc oxide.

18. The light-emitting element according to claim 16,
wherein the metal oxide is titanium oxide.

19. The light-emitting element according to claim 15,
wherein the second electrode is a cathode.

20. (canceled)

21. The light-emitting element according to claim 1,
wherein the particle has a particle size of 1/10 or less of a peak emission wavelength of the light-emitting layer.

22. The light-emitting element according to claim 1,
wherein, for the gap, a ratio of a gap width to a thickness of the second electrode is 1.0 or less.

23. (canceled)

24. (canceled)

25. The light-emitting element according to claim 1,
wherein the gap has an opening facing the particle layer and an opening not facing the particle layer, the opening facing the particle layer having a width positioned on another face of the second electrode, and the width of the opening facing the particle layer being smaller than a width of the opening not facing the particle layer.

26. The light-emitting element according to claim 1, further comprising
another particle layer,
wherein the particle layer is in contact with one of an upper surface or a lower surface of the second electrode, and the other particle layer is in contact with another one of the upper surface or the lower surface.

27. The light-emitting element according to claim 1,
wherein the particles scatters light amplified by plasmons generated in the gap.

28. (canceled)

29. A display device comprising the light-emitting element according to claim 1.
